(19) United States
(12) Patent Application Publication
(10) Pub. No.: US 2017/0197279 A1
(43) Pub. Date: Jul. 13, 2017

(54) APPARATUS AND METHODS FOR PERFORMING LASER ABLATION ON A SUBSTRATE

(71) Applicant: M-SOLV LTD., Oxford (GB)

(72) Inventors: David Charles MILNE, Chipping Norton (GB); Philip Thomas RUMSBY, Woodstock (GB); David Thomas Edmund MYLES, Oxford (GB)

(73) Assignee: M-SOLV LTD., Oxford (GB)

(21) Appl. No.: 15/321,487

(22) PCT Filed: Aug. 19, 2015
(86) PCT No.: PCT/GB2015/052413

§ 371 Date: Dec. 22, 2016

(30) Foreign Application Priority Data
Aug. 26, 2014 (GB) 1415083.3

(51) Int. Cl. B23K 26/386; B23K 26/082; H05K 3/00; B23K 26/06

(52) U.S. Cl. CPC B23K 26/386; B23K 26/0643; B23K 26/0648; B23K 26/082; H05K 3/0035; B23K 2201/42

(57) ABSTRACT

Apparatus and methods are disclosed for performing laser ablation. In an example arrangement a spatial light modulator (54) is used to modulate a pulsed laser beam from a solid state laser (52). A two-stage de-magnification process (58, 62) is used to allow radiation intensity to be kept relatively low at the spatial light modulator (54) while allowing access to feedback sensors (64) in an intermediate imaging plane.

This invention relates to performing laser ablation on a substrate using a solid state laser and a programmable spatial light modulator.

Lasers are widely used in the manufacture of advanced printed circuit boards (PCBs). A particularly well known example is the drilling of blind contact holes, so called micro-vias, in multi-layer PCBs. In this case ultra violet (UV) solid state lasers are often used to drill through a top copper layer and an underlying dielectric layer to allow contact to be made to a lower copper layer. In some cases, the cost effectiveness of this process is improved by using two different laser processes to remove the two different materials. A UV diode pumped solid state (DPSS) laser is usually used to drill the holes in the top copper layer to expose the lower dielectric layer and in a separate process a CO2 laser is used to remove the dielectric material exposed below each hole.

Recently a new type of high density multi-layer circuit board manufacturing technology has been proposed. US2005/0041398A1 and publication “Unveiling the next generation in substrate technology”, Huemoeller et al, 2006 Pacific Micro-electronics Symposium describe the concept of “laser-embedded circuit technology”. In this new technology, lasers are used to directly ablate fine grooves, larger area pads and also contact holes in organic dielectric substrates. The grooves connect to the pads and contact holes so that, after laser structuring and subsequent metal plating, a first layer consisting of a complex pattern of fine conductors and pads embedded in the top surface of the dielectric layer is formed together with a second layer consisting of deeper contact holes connecting to a lower metal layer. More information on the progress of this new technology was presented in papers EU165 (David Baron) and TW086-2 (Yuel-Ling Lee & Barbara Wood) at the 12^{th} Electronic Circuit World Convention in Taiwan, Nov. 9-11, 2011.

Up to now pulsed UV lasers have been used in such methods to form the grooves, pads and contact holes in a single process using either direct write or mask imaging methods.

The direct write approach generally uses a beam scanner to move a focussed beam from a laser over the substrate surface to scribe the grooves and also create the pad and contact hole structures. This direct write approach uses a highly focusable beam from a UV diode pumped solid state (DPSS) lasers with high beam quality and hence is very well suited to the fine groove scribing process. It is also able to deal well with the different layer depth requirements associated with pad and contact hole structures. By this method, grooves, pads and contact holes of different depth can be readily formed. However, since the low pulse energy of the UV DPSS lasers require a very small focussed spot to enable ablation, which is convenient for creating narrow tracks and holes, it is not an efficient method for removing material from larger area features and ground planes. This direct write method also has difficulty maintaining constant depth at the intersections between grooves and pads. A description of direct write laser equipment suitable for making PCBs based on embedded conductors was presented in paper TW086-9 (Weiming Cheng & Mark Unrath) at the 12^{th} Electronic Circuit World Convention in Taiwan, Nov. 9-11, 2011.

The mask imaging approach generally uses a UV excimer laser to illuminate a mask containing the full detail of one layer or level of the circuit design. An image of the mask is de-magnified onto the substrate such that the full area of the circuit on that layer is reproduced on the substrate with a laser pulse energy level sufficient to ablate the dielectric material. In some cases, where the circuit to be formed is large, relative synchronized motion of the mask and substrate is used to transfer the full pattern. Excimer laser mask projection and associated strategies for covering large substrate areas have been known for many years. Proc SPIE 1997, vol. 3223, p 26 (Harvey & Rumsby) gives a description of this approach.

Since the whole area of the mask is illuminated during the image transfer process, this approach is insensitive to the total area of the individual structures to be created and hence is well suited to creating both the fine grooves, the larger area pads and ground planes. It is also excellent at maintaining depth constancy at the intersections between grooves and pads. However, except in the case where the circuitry is extremely dense, this mask imaging approach is significantly more costly than the direct write approach since the purchase and operating costs of excimer lasers are both very high. Mask imaging is also very inflexible in that a new mask needs to be used for each layer of the circuit.

The latter limitation is overcome in the arrangement described in publication US 2008/0145567 A1. In this case, an excimer laser scanning mask projection system is used to form a layer consisting of grooves and pads to the same depth in the insulating layer and, in a separate process, using a second laser which is delivered by a separate beam delivery system, the deeper contact holes penetrating to an underlying metal layer are formed. This two-step process is a way of dealing with the varying depth structure requirements. However, it still suffers from the high cost associated with the use of excimer lasers.

WO 2014/0688274 A1 discloses an alternative approach in which a spot formed by a solid state laser is raster scanned over a mask. An image of the mask pattern, illuminated by the solid state laser, is then projected onto a substrate and a structure corresponding to the mask pattern is formed by ablation. This approach avoids the need for expensive excimer lasers but is still subject to the inflexibilities associated with the use of masks. A different mask or a different region on a mask is needed for each layer of the structure to be formed. If a modification to the structure being formed is needed then an entirely new mask may be needed. If errors attributable to the mask pattern are detected in the structure being formed then a new mask may be needed.

It is an object of the invention at least partly to address one or more of the problems with the prior art mentioned above. In particular, it is an object of the invention to provide apparatus and methods for performing laser ablation that allow high throughput, low cost, high flexibility, and/or high levels of control and/or reliability.

According to an aspect of the invention there is provided an apparatus for performing laser ablation on a substrate, comprising: a solid state laser configured to provide a pulsed laser beam; a programmable spatial light modulator configured to modulate the pulsed laser beam with a pattern defined by a control signal input to the modulator; a scanning system configured to form an image of the pattern selectively at one of a plurality of possible locations in a first imaging plane; and a controller configured to control the scanning system and spatial light modulator to form in sequence a plurality of the images of the pattern at different locations in the first imaging plane.

The use of a solid state laser rather than an excimer laser reduces cost of ownership significantly. Additionally, an excimer laser would typically have to be run below its maximum power in order not to damage the spatial light modulator, thereby reducing efficiency.

The use of a spatial light modulator allows the pattern of ablation on the substrate to be changed dynamically, thereby increasing flexibility and control.

High resolution prior art systems that use spatial light modulation tend to use fixed optics (i.e. without scanning capability) to project a pattern defined by the spatial light modulator onto a target for the pattern (e.g. a substrate). The fixed optics may de-magnify the pattern so that the pattern formed on the substrate is a smaller version of the pattern defined on the spatial light modulator. The de-magnification facilitates illuminating the spatial light modulator with low enough pulse energy density to avoid damage to it, while providing a high enough energy density at the substrate to ablate the surface of a substrate. The demagnification also facilitates formation of fine features on the substrate. If patterns defined by the spatial light modulator need to be formed at different positions on the substrate then the substrate can be scanned relative to the spatial light modulator. The use of fixed optics simplifies design requirements for the optics and facilitates the formation of patterns with high accuracy. In the context of laser ablation, however, it is desirable to be able to irradiate large regions of the substrate at high speed. One approach for achieving this might be to provide a spatial light modulator with a very large number of individually addressable elements (e.g. a large number of micro-mirrors). In this way a larger portion of the pattern can be projected onto the substrate, for each position of the substrate, than would be possible using a spatial light modulator with a smaller number of elements. However, providing a spatial light modulator having more elements may be more expensive. The spatial light modulator may need to be larger, which may make the spatial light modulator more difficult to illuminate accurately (e.g. uniformly). It may be more difficult to illuminate the pattern defined by such a spatial light modulator accurately onto the substrate.

An alternative approach is to scan the substrate more quickly. However, this requires sophisticated motors and substrate table arrangements in order to provide the necessary accelerations and positional accuracy.

DPSS lasers, for example, are widely tunable in their parameter settings. This makes it possible for them to deliver relatively low pulse energies at high frequencies whilst maintaining full power. Utilising the full power of the laser at the high frequencies would typically create a requirement for a relative speed between the substrate and beam in the order of several metres per second. Such relative speeds are difficult to achieve using substrate scanning only.

The solution provided according to the present embodiment is to scan the image from the spatial light modulator instead of (or in addition to) scanning the substrate. In this way, complex patterns can be rapidly formed over a wide region on the substrate without requiring spatial light modulators having very large numbers of elements (although these could still be used) nor complex mechanisms for rapid scanning of the substrate (although these could still be used). Scanning of the image of the spatial light modulator requires more complex optics than is typically the case for a fixed (non-scanning) optical system, but the inventors have recognised that the gains in terms of increased throughput and/or reduced cost and complexity in the spatial light modulator and/or substrate scanning system (if any) outweigh any challenges associated with implementing the more complex optics. In the example discussed above the use of a DPSS laser is proposed which would require movement of the substrate at speeds in the order of several meters per second. While generating movements of the substrate at these speeds may be impractical, the generation of equivalent scanning speeds based on the use of a beam scanner to scan a laser beam is well within the range of operation of currently available laser beam scanners.

In an embodiment, the substrate is positioned in the first imaging plane. Positioning the substrate in the first imaging plane simplifies the overall optical requirements of the apparatus.

In an embodiment, the apparatus further comprises a projection system configured to form the plurality of images of the pattern at different locations on the substrate and a final element of the projection system is configured to be held stationary relative to the spatial light modulator while the plurality of images of the pattern at different locations in the first imaging plane are formed. Thus, the final element of the projection system is not directly involved in any scanning process. Having a stationary final element of the projection system (or an entirely stationary projection system) facilitates arranging of apparatus for removing debris produced by the ablation process (e.g. suction equipment).

In an alternative embodiment, the substrate is provided in a second imaging plane and the apparatus further comprises a projection system that projects a de-magnified version of the image in the first imaging plane onto the substrate in the second imaging plane.

Thus, an image of the spatial light modulator is formed in an imaging plane (referred to here as the first imaging plane) that is at an intermediate position between the substrate and the spatial light modulator. This arrangement makes it possible for the first imaging plane to be accessed by sensors or other devices in a way which is not possible if the first imaging plane is not provided at an intermediate position. When the substrate is provided at the first imaging plane, for example, the presence of the substrate inhibits access by sensors or other devices. Allowing access by sensors or other devices to an image formed by the spatial light modulator makes it possible to measure properties of the image. For example, parameters relating to the quality of the image may be measured. The measurements may be used to control operation of the scanning system and/or spatial light modulator, for example in a feedback arrangement.

Measuring properties of the image (in the first imaging plane) after the image has been scanned and/or de-magnified makes it possible to detect errors introduced by the scanning and/or de-magnifying process(es). In systems using spatial light modulators which do not have an accessible intermediate imaging plane, the image can only be checked at the output of the spatial light modulator and/or at the substrate itself.

In an embodiment of this type a final element of the projection system may also be configured to be held stationary relative to the spatial light modulator while the plurality of images of the pattern at different locations in the first imaging plane are formed. Thus, the final element of the projection system is not directly involved in any scanning process. As discussed above, having a stationary final element of the projection system (or entirely stationary projection system) facilitates arrangement of apparatus for removing debris produced by the ablation process.

In an embodiment, the scanning system is configured so that the image of the pattern formed in the first imaging plane is de-magnified relative to the pattern at the spatial light modulator. De-magnifying the pattern at the spatial light modulator reduces the intensity that is needed at the spatial light modulator to allow ablation to be carried out at the substrate. For many types of spatial light modulator there is a limit to the radiation intensity that can be handled by the spatial light modulator without risk of damage or shortened lifespan. De-magnifying the pattern between the spatial light modulator and the first imaging plane also facilitates the formation of finer structures on the substrate.

In an embodiment, the de-magnification of the pattern between the spatial light modulator and the first imaging plane is carried out in the context of an embodiment in which the substrate is provided in a second imaging plane and the apparatus further comprises a projection system that projects a de-magnified version of the image in the first imaging plane onto the substrate in the second imaging plane. Thus, a two-stage de-magnification process is used. The use of a two-stage de-magnification further facilitates providing a desired overall de-magnification between the spatial light modulator and the substrate by reducing the de-magnification requirements of any one stage and also providing enhanced flexibility. The overall de-magnification can be adjusted according to requirements by replacing or modifying one of the two stages but not the other of the two stages.

According to an alternative aspect, there is provided a method of performing laser ablation on a substrate, comprising: using a solid state laser to provide a pulsed laser beam; inputting a control signal to a programmable spatial light modulator to modulate the pulsed laser beam with a pattern; and forming in sequence a plurality of images in a first imaging plane of patterns defined by the spatial light modulator, the plurality of images being formed at different locations in the first imaging plane.

As in the embodiments discussed above, the substrate may be positioned in the first imaging plane. As in the embodiments discussed above, the substrate may alternatively be provided in a second imaging plane and the method may further comprise projecting a de-magnified version of the image in the first imaging plane onto the substrate in the second imaging plane.

The invention will now be further described, merely by way of example, with reference to the accompanying drawings, in which:

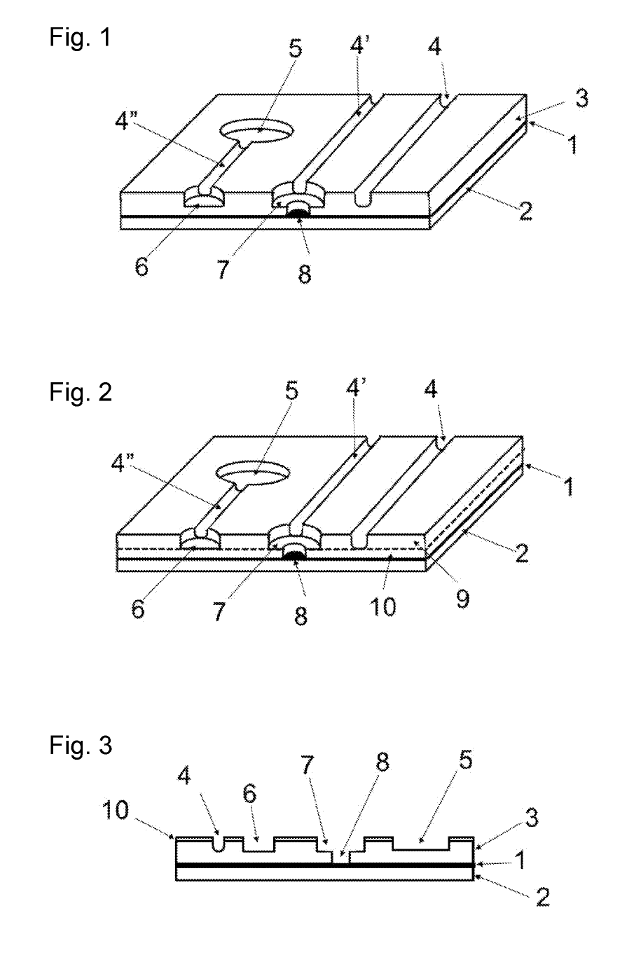

FIG. 1 is a perspective view of a typical HDI printed circuit board showing the type of structures required to be formed therein;

FIG. 2 is a perspective view similar to FIG. 1 in which the printed circuit board comprises an upper and lower dielectric layer;

FIG. 3 is a sectional view of another typical printed circuit board having a thin protective or sacrificial layer formed thereon;

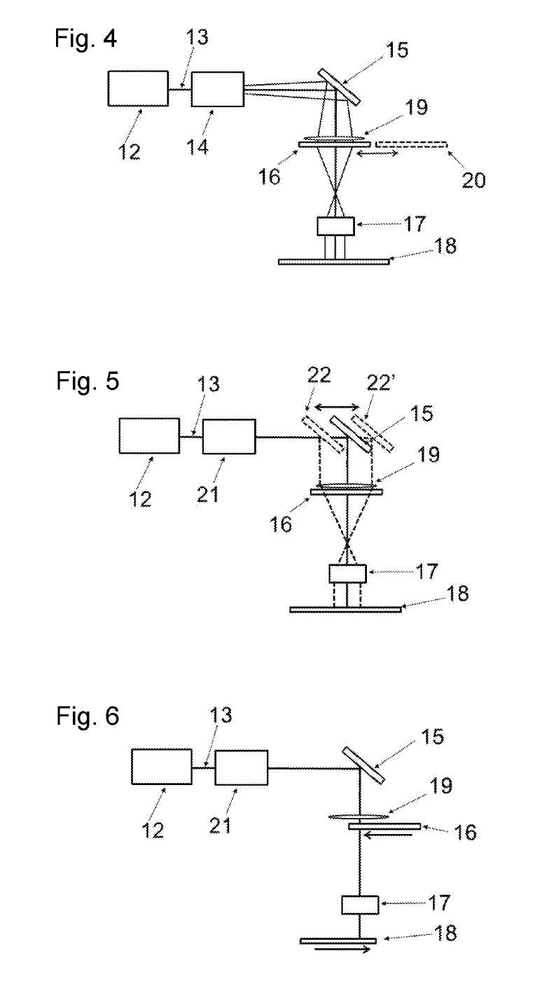

FIG. 4 is a schematic diagram of known apparatus for forming embedded structures in a dielectric layer;

FIG. 5 is a schematic diagram of another known apparatus for forming embedded structures in a dielectric layer;

FIG. 6 is a schematic diagram of further known apparatus for forming embedded structures in a dielectric layer;

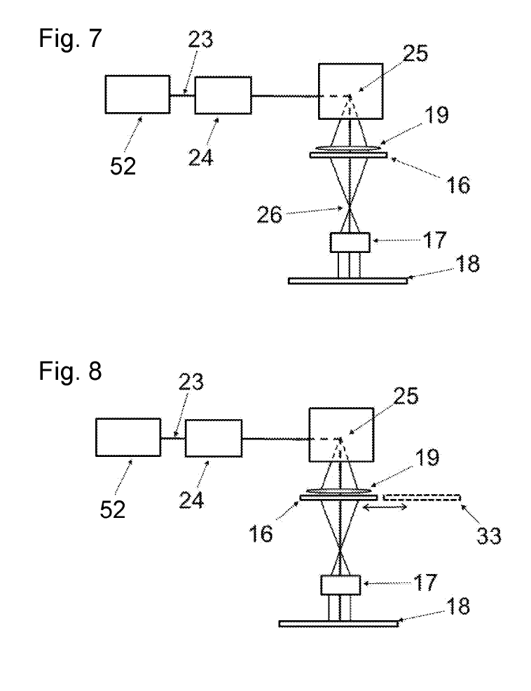

FIG. 7 is a schematic diagram of further known apparatus for forming embedded structures in a dielectric layer;

FIG. 8 is a schematic diagram of further known apparatus for forming embedded structures in a dielectric layer;

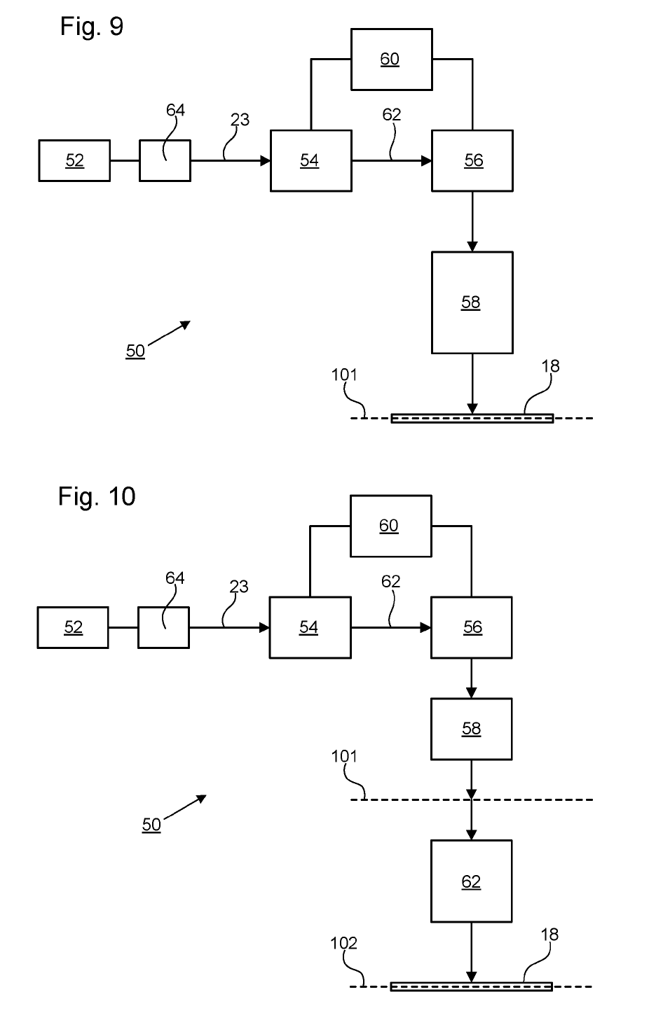

FIG. 9 is a schematic diagram of an apparatus for performing ablation according to an embodiment;

FIG. 10 is a schematic diagram of an apparatus for performing ablation according to a further embodiment;

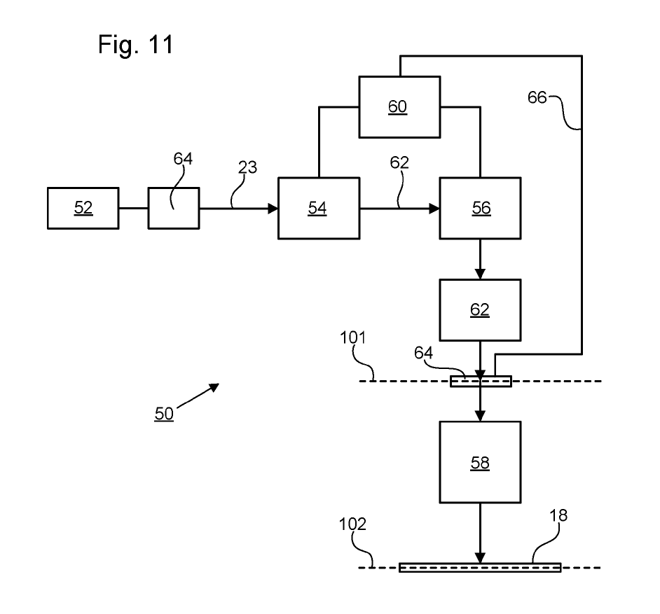

FIG. 11 is a schematic diagram of an apparatus for performing ablation according to a further embodiment.

FIG. 1 shows a section of a high density interconnect (HDI) printed circuit board (PCB) or integrated circuit (IC) substrate and indicates the type of “embedded” structures that are required to be formed. A copper layer 1, patterned to form an electrical circuit, is supported on a dielectric core layer 2. The copper layer 1 is over coated with an upper dielectric layer 3 into which various structures have been formed by laser ablation. Grooves 4, 4′ and 4″, large pad 5 and small pads 6 and 7 all have the same depth which is less than the full thickness of the upper dielectric layer 3. For IC substrates, groove widths and pad diameters required are typically in the range 5 to 15 microns and 100 to 300 μm, respectively, with depths in the range 5 to 10 microns. For HDI PCBs, grooves may be wider and deeper. Contact hole (or via) 8 inside pad 7 is formed by laser ablation to a greater depth such that all the upper dielectric layer material is removed to expose an area of the copper circuit below. Contact hole depths may be typically twice the depth of pads and grooves.

FIG. 2 shows a similar section of an HDI PCB or IC substrate as FIG. 1 but in this case the upper dielectric layer on top of the copper layer consists of two layers of different material, upper dielectric layer 9 and lower dielectric layer 10. Grooves 4, 4′ and 4″, large pad 5 and small pads 6 and 7 all penetrate the upper layer 9 completely but do not significantly penetrate the lower layer 10. Contact hole 8 penetrates the lower dielectric layer 10 completely to expose an area of the copper circuit below.

FIG. 3 shows a section through an HDI PCB where a thin protective or sacrificial layer of material 11 has been applied to the top side of the dielectric layer 3 before laser patterning of the structures. Such protective layers are generally at most only a few microns thick and their main purpose is to protect the top surface of the dielectric layer 3 from damage during the laser ablation process. During laser ablation of the structures, the beam penetrates the material of the protective layer and removes material to the required depth in the dielectric layer 3 below. After completion of the laser ablation process and before subsequent processes, the protective layer is usually removed to expose the dielectric material.

FIG. 4 shows known apparatus as commonly used to create embedded structures in dielectric layers. Excimer laser 12 emits a pulsed UV beam 13 which is shaped by homogenizer unit 14, deviated by mirror 15 and illuminates the whole of mask 16 uniformly. Projection system 17 de-magnifies the image of the mask onto the surface of the dielectric coated substrate 18 such that the energy density of the beam at the substrate 18 is sufficient to ablate the dielectric material and form structures in the layer corresponding to the mask pattern.

Lens 19 is a field lens that serves to control the beam entering the lens 17 such that it performs in an optimum way. On each laser pulse the pattern on the mask is machined into the surface of the dielectric to a well-defined depth. Typically, the depth machined by each laser pulse is a fraction of a micron so many laser pulses are required to create grooves and pads with depth of many microns. If features of different depth are required to be machined into the substrate surface then the mask that defines the first level is exchanged for another mask 20 that defines the deeper level after which the laser ablation process is repeated.

To illuminate the full area of each mask and the corresponding area on the substrate with one laser pulse requires pulses with high energy from the laser. For example, if the size of the device to be made is 10×10 mm (1 cm²) and since the pulse energy density required for efficient ablation is about 0.5 J/cm² then the total energy per pulse required at the substrate is 0.5 J. Because of losses in the optical system, significantly more energy per pulse is required from the laser. UV excimer lasers are very appropriate for this application since, typically, they operate with high pulse energies at low repetition rate. Excimer lasers emitting output pulse energies up to 1 J at repetition rates up to 300 Hz are readily available. Various optical strategies have been devised to allow the manufacture of larger devices or allow the use of excimer lasers with lower pulse energy.

FIG. 5 shows prior art illustrating such a case where beam shaping optics 21 are arranged to create a line beam at the surface of the mask 16. This line beam is sufficiently long to cover the full width of the mask. The line beam is scanned over the surface of the mask in a direction perpendicular to the line by the 1D motion of mirror 15. By moving mirror 15 in a line from position 22 to 22′ the whole area of the mask is sequentially illuminated and correspondingly the whole area to be machined on the substrate is sequentially processed. Mask, projection system and substrate are all maintained stationary while mirror 15 is moved.

The mirror is moved at a speed that allows the correct number of laser pulses to impact each area of the substrate to create structures of the required depth. For example for an excimer laser operating at 300 Hz and a line beam at the substrate with a width of 1 mm and where each laser pulse removes material to a depth of 0.5 microns then 20 laser pulses per area are required to create structures with depth of 10 microns. Such an arrangement requires the line beam to move across the substrate at a speed of 15 mm/sec. The speed of the beam at the mask is greater than that at the substrate by a factor equal to the de-magnification factor of the lens

FIG. 6 shows another known arrangement and illustrates an alternative way to deal with the limited laser pulse energy issue. This involves moving both the mask and substrate in an accurately linked way with respect to a beam that is stationary. Beam shaping optics 21 form a line beam with a length that spans the full width of the mask. In this case, mirror 15 remains stationary and the mask 16 is moved linearly as shown. In order to generate an accurate image of the mask on the substrate, it is necessary for the substrate 18 to move in the opposite direction to the mask as shown at a speed that is related to that of the mask by the de-magnification factor of the imaging lens 17. Such 1D mask and substrate linked motion systems are well known in excimer laser wafer exposure tools for semiconductor manufacturing.

Excimer lasers have also been used with 2D mask and substrate scanning schemes in situations where the area of the device to be processed is very large and there is insufficient energy in each laser pulse to create a line beam across the full width of the device. Proc SPIE., 1996 (2921), p684 describes such a system. Such systems are very complex requiring highly accurate mask and work-piece stage control and, in addition, obtaining uniform ablation depth in the regions on the substrate where the scan bands overlap is very difficult to control.

FIG. 7 shows a known arrangement in which a solid state laser is used instead of a UV excimer laser. The arrangement is otherwise similar to those shown in FIGS. 4, 5 and 6 in that a mask projection optical system is used is used to define the structure of the circuit layer in the substrate.

A laser 52 emits output beam 23 which is shaped by optics 24 to form a circular or other shaped spot of appropriate size at the mask 16 such that, after imaging onto the substrate surface 18 by lens 17, the energy density is sufficient to ablate the material on the surface of the substrate 18. 2D scanner unit 25 moves the spot over the mask 16 in a 2D raster pattern such that the full area of the mask 16 is covered and, correspondingly, the full area to be processed at the substrate 18 is also covered imprinting the image of the pattern on the mask 16 into the substrate surface. The lens 17 may have a telecentric performance on the image side. This means that a parallel beam is formed by the lens so that variations in the distance to the substrate do not change the size of the image. This avoids the need to position the substrate with great accuracy along the optical axis and allows any non-flatness of the substrate to be accommodated.

A lens 19 is provided that images a plane between the mirrors of the scanner 25 into the entrance pupil 26 of the lens 17 so that the conditions for telecentric performance are met. It is important that the lens 17 has sufficient optical resolution to accurately form well defined structures down to 5 μm or less in the surface of the dielectric layer. The resolution is determined by the wavelength and numerical aperture and for a laser wavelength of 355 nm, this translates to a numerical aperture of about 0.15 or greater.

The other requirement for the lens 17 is that it de-magnifies the pattern on the mask onto the substrate such that the energy density of laser pulses at the substrate is high enough to ablate the material but the energy density at the mask is low enough such that the mask material, which may be a patterned chrome layer on a quartz substrate, is not damaged. A lens magnification factor of 3× or more is found to be appropriate in most cases. An energy density of 0.5 J/cm² at the substrate is generally sufficient to ablate most polymer dielectric materials and hence with a lens de-magnification of 3× and, allowing for reasonable losses in the lens, the corresponding energy density at the mask is less than 0.07 J/cm², a level that is well below the damage level of a chrome on quartz mask.

FIG. 8 shows one way of creating a two layer structure using the arrangement of FIG. 7. A first mask 16 is scanned over its full area to create the upper layer groove and pad structure following which the first mask 16 is replaced with a second mask 33 which has the pattern associated with the lower layer via structure. Accurate registration of the masks is, of course, required to ensure that the two laser machined patterns are superimposed on the substrate surface accurately. Such a multiple, sequential scanned mask approach is preferred when the lower layer pattern has a high density of features such that scanning all or a large part of the lower layer mask is efficient. If, on the other hand, only a few deeper features such as vias located within pad areas defined by the upper layer mask are required then alternative methods are possible. For example, a “point and shoot” method, in which the laser is held stationary for an extended period of time at the position of the via (rather than being scanned over the whole mask), may be used.

Embodiments of the invention are depicted in FIG. 9 onwards and described below.

An apparatus 50 for performing laser ablation on a substrate 18 is provided. The apparatus 50 comprises a solid state laser 52. The solid state laser may be configured to provide a pulsed laser beam. The solid state laser 52 may be a Q-switched CW diode pumped solid state (DPSS) laser. Such a laser operates in a very different way to an excimer laser, emitting pulses with low energy (e.g. 0.1 mJ to few 10s of mJ) at a high (multiple kHz to 100 kHz) repetition rate. Q-switched DPSS lasers of many types are now readily available. In an embodiment a multimode DPSS laser operating in the UV region is used. UV is suitable for ablation of a wide range of dielectric materials and optical resolution of imaging lenses is superior compared to longer wavelengths. In addition, the incoherent nature of multimode laser beams allow a high resolution image to be illuminated without suffering the effects of diffraction. Single mode lasers are less suitable for illuminating an image, although they are good for focussing to discrete small spots. Other pulsed DPSS lasers with longer wavelength and with lower mode beam output may also be used.

For example, UV MM CW diode pumped solid state lasers can be used that operate at a wavelength of 355 nm giving powers of 20, 40 or 80 W at a repetition rate of around 10 kHz so giving output pulse energies of 2, 4 and 8 mJ, respectively. Another example is an MM UV DPSS laser which gives 40 W at a repetition rate of 6 kHz and hence giving 6.7 mJ per pulse. Further examples are UV lower mode CW diode pumped solid state lasers that can be operated at a wavelength of 355 nm giving powers of 20 or 28 W at a repetition rate of around 100 kHz and hence giving output pulse energies of 0.2 and 0.28 mJ, respectively.

An output beam 23 from the laser 52 is directed, directly or indirectly, onto a programmable spatial light modulator 54. In an embodiment (as shown), the apparatus 50 comprises a beam shaper 64. The beam shaper 64 may be configured to modify the energy profile in the output beam 23. For example, the beam shaper 64 may be configured to impose a top-hat intensity profile on the beam 23.

A spatial light modulator is a device that is capable of imposing a spatially varying modulation on a beam of light. A programmable spatial light modulator is a modulator that can change the modulation in response to a control signal. The control signal may be provided by a computer. In an embodiment, the modulator 54 comprises an array of micro-mirrors. In an embodiment the array is a two-dimensional array. Each of the micro-mirrors may be individually addressable, such that a control signal can specify independently for each mirror whether the mirror reflects radiation in a direction which will cause it to reach the substrate or in a direction which will prevent it from reaching the substrate (e.g. by directing it instead towards a radiation sink where it is absorbed). Other forms of spatial light modulator are also known in the art and could be used in the context of embodiments of the present invention.

In the embodiment shown, the modulator 54 is configured to modulate the pulsed laser beam with a pattern defined by a control signal provided by a controller 60. An output beam 62 from the modulator 54 is input to a scanning system 56. The scanning system 56 may comprise a two-dimensional beam scanner for example. The scanning system 56 is configured to form an image of the pattern selectively at one of a plurality of possible locations in a first imaging plane 101. In an embodiment, the plurality of possible locations are different with respect to each other in the reference frame of the modulator 54. The controller 60 is configured to control the scanning system 56 and spatial light modulator 54 to form in sequence (at different times, for example one after the other) a plurality of the images of the pattern at different locations in the first imaging plane. In an embodiment the different locations are different with respect to each other in the reference frame of the modulator 54. In an embodiment, the modulator 54 remains stationary during the forming of the plurality of images at the different locations in the first imaging plane. In the embodiment shown in FIG. 9, the substrate 18 is provided in the first imaging plane 101. In other embodiments, as described below, the substrate 18 may be provided in a different plane. The sequence of images may be formed in a raster-scan pattern. Optionally, the images are shaped so as to tessellate with each other. In this way a region larger than an individual image can be patterned in a continuous manner (without gaps) by the scanned sequence of images. For example each of the individual images may be square or rectangular and the images may be scanned so as to continuously cover a region consisting of a larger square or rectangle.

In an embodiment, the scanning system 56 is configured so that the image of the pattern formed in the first imaging plane 101 is de-magnified relative to the pattern at the spatial light modulator 54. Thus an image of the pattern that is smaller than the pattern formed on the spatial light modulator 54 is formed on the first imaging plane 101. In the example shown in FIG. 9, the de-magnification is achieved by one or more suitably configured optical elements in a projection system 58.

In an embodiment, a final element of the projection system 58 (i.e. the last element along the optical path leading to the substrate) is configured to be held stationary relative to the modulator 54 during the scanning of the image over the substrate 18. Ablation therefore takes place in a localized area (underneath the stationary final element). If the final element were allowed to be move, for example so as to take part in the scanning of a pattern over the substrate, ablation would occur over a wider range of positions. Restricting the range of positions over which ablation can occur makes it easier to arrange for effective debris removal. Debris removal apparatus can be compact and/or mounted simply (e.g. in a permanent position rather than in a way in which it can be moved around in order to track an ablation process in real time).

In an embodiment, the controller 60 is configured such each image in the sequence of images formed on the substrate 18 is formed from a different single pulse from the laser 52. This is not essential. In other embodiments the controller 60 may arrange for each of one or more of the images in the sequence of images to be formed by two or more different pulses from the laser. In an embodiment the modulator 54 is able to modulate the pulsed laser beam with a different pattern between successive pulses of the laser 52. This enables the pattern to be changed from one pulse to the next pulse, thereby facilitating the irradiation of complex patterns on the substrate (e.g. patterns that are formed from sequences of images that change from one image to the next for at least a subset of the sequence of images).

FIG. 10 depicts an example of an arrangement in which the substrate 18 is provided in a second imaging plane 102. The second imaging plane 102 is downstream from the first imaging plane 101. Like in the embodiment of FIG. 9, the scanning system 56 is still configured to form an image of the pattern formed by the modulator 54 selectively at one of a plurality of possible locations in the first imaging plane 101. A projection system 62 is provided that project a de-magnified version of the image in the first imaging plane 101 onto the substrate 18 in the second imaging plane 102. The projection system 62 projects the plurality of images of the pattern formed at different locations in the first imaging plane 101 onto a corresponding plurality of locations on the substrate 18.

In the particular example shown in FIG. 10 the apparatus 50 comprises two projection systems: a first projection system 58 and a second projection system 62. The first projection system 58 may be configured in the same or similar manner as the projection system 58 described above with reference to FIG. 9. The first projection system 58 may for example form a de-magnified image in the first imaging plane 101 of a pattern formed on the modulator 54. The second projection system, as described above, projects a de-magnified version of the image in the first imaging plane 101 onto the substrate 18. This embodiment therefore provides a two-stage de-magnification process.

As discussed above in the introductory part of the description, arranging the optics of the apparatus 50 so the first imaging plane 101 is at an intermediate position between the substrate 18 and the modulator 54 increases the extent to which the first imaging plane 101 can be accessed. For example, it is possible (or easier) for the first imaging plane 101 to be accessed by sensors or other devices in a way which is not possible if the first imaging plane 101 is not provided at an intermediate position. When the substrate 18 is provided at the first imaging plane 101, for example, the presence of the substrate 18 inhibits access by sensors or other devices.

In an embodiment, a sensor 64 is provided in or adjacent to the first imaging plane 101. An example of such an embodiment is shown in FIG. 11. The sensor 64 may be configured to measure a property of the image formed in the first imaging plane 101. The property may comprise one or more of the following for example: a measure of the quality of focus, a measure of the positional accuracy of one or more features in the pattern, a measure of the width of features such as lines or spaces between lines (e.g. a minimal line width or space), a measure of intensity accuracy (e.g. uniformity of intensity over regions which are intended to have the same intensity).

In an embodiment, the controller 60 is configured to use the measured property measured by the sensor 64 to control operation of one or both of the modulator 54 and the scanning system 56. For example, the controller 60 may be configured to respond to a deviation in image quality detected by the sensor 64 by modifying an operating characteristic of the scanning system, such as a nominal scanning path. Alternatively or additionally, the controller 64 may respond to the deviation by modifying an operating characteristic of the modulator 54. For example an image formed on the modulator 54 may be modified to compensate for a distortion or other error detected in the first imaging plane 101 by the sensor 64. The sensor 64 may be connected to the controller 60 via a connection line 66. The sensor 64 may be configured to operate in a feedback loop.

The embodiment of FIG. 11 is the same as the embodiment discussed above with reference to FIG. 10 except for the presence of the sensor 64 and for the connecting line 66 between the sensor 64 and the controller 60.

Scanning of the image defined by the modulator 54 over different positions in the first imaging plane 101 may introduce distortions to the image. This may occur for example due to a different optical path length existing between the modulator 54 and different positions within the first imaging plane 101. Distortions may be larger for scanning positions that are further away from the optical axis than for those that are nearer to the optical axis. In an embodiment, these and/or other distortions may be at least partially corrected for by adjusting the pattern defined by the modulator 54 as a function of the position at which the image of the pattern is to be formed in the first imaging plane 101. Calibration measurements may be performed to obtain calibration data defining how the patterns defined by the modulator 54 should be adjusted.

In any of the embodiments discussed above, or in other embodiments, the scanning system 56 may be a 1D, 2D or 3D scanning system. The scanning system may for example comprise a 1D, 2D or 3D beam scanner and an associated optical (e.g. lens) system configured to form an image from an output from the beam scanner. When the scanning system 56 is a 1D scanning system, the scanning system 56 may be configured to scan the image of the pattern on the modulator 54 along a scanning line (e.g. a straight line) and the apparatus may be configured to move the substrate 18 along a direction that is perpendicular to the scanning line. Such a configuration may be used for example to create a raster scan of the image on the substrate 18. When the scanning system 56 is a 2D scanning system, the scanning system 56 may be capable of positioning an image of the pattern on the modulator 54 arbitrarily displaced relative to two mutually perpendicular axes that are perpendicular to the optical axis in the first imaging plane. When the scanning system 56 is a 3D scanning system, the scanning system 56 may be capable of positioning an image of the pattern on the modulator arbitrarily in three dimensions in the region of the first imaging plane. This configuration may be capable of positioning the image in the same way as the 2D scanning system but with the additional possibility of varying the focal position along a direction parallel to the optical axis. This functionality may be useful for correcting focus errors that might otherwise occur due to the increase in optical path at positions in the first imaging plane that are further away from the optical axis.

1. An apparatus for performing laser ablation on a substrate, comprising:
a solid state laser configured to provide a pulsed laser beam;
a programmable spatial light modulator configured to modulate the pulsed laser beam with a pattern defined by a control signal input to the modulator;
a scanning system configured to form an image of the pattern selectively at one of a plurality of possible locations in a first imaging plane; and
a controller configured to control the scanning system and spatial light modulator to form in sequence a plurality of the images of the pattern at different locations in the first imaging plane.

2. The apparatus of claim 1, wherein the substrate is positioned in the first imaging plane.

3. The apparatus of claim 2, further comprising a projection system configured to form the plurality of images of the pattern at different locations on the substrate, and wherein a final element of the projection system is configured to be held stationary relative to the spatial light modulator while the plurality of images of the pattern at different locations in the first imaging plane are formed.

4. The apparatus of claim 1, wherein:
the apparatus further comprises a projection system configured to de-magnify the image formed in the first imaging plane and project the de-magnified image onto the substrate in a second imaging plane; and
the projection system is configured to project the plurality of images of the pattern formed at different locations in the first imaging plane onto a corresponding plurality of locations on the substrate.

5. The apparatus according to claim 4, wherein a final element of the projection system is configured to be held stationary relative to the spatial light modulator while the plurality of images of the pattern at different locations in the first imaging plane are formed.

6. The apparatus of claim 4, further comprising a sensor configured to measure a property of the image formed in the first imaging plane.

7. The apparatus of claim 6, wherein the controller is configured to use the measured property measured by the sensor to control operation of one or both of the spatial light modulator and the scanning system.

8. The apparatus of claim 1, wherein the scanning system is configured so that the image of the pattern formed in the first imaging plane is de-magnified relative to the pattern at the spatial light modulator.

9. The apparatus of claim 1, wherein the controller is configured such that each image in said sequence can be formed from a different single pulse from the solid state laser.

10. The apparatus of claim 1, wherein the programmable spatial light modulator is configured to be able to modulate the pulsed laser beam with a different pattern between successive pulses of the solid state laser such that the pattern can be changed from one pulse to the next pulse.

11. The apparatus of claim 1, wherein the controller is configured to control the spatial light modulator to modify the pattern to be formed in the first imaging plane as a function of the position where the pattern is to be formed in the first imaging plane.

12. The apparatus according to claim 1, wherein the spatial light modulator comprises an array of mirrors.

13. The apparatus of claim 1, wherein the different locations are different with respect to each other in the reference frame of the programmable spatial light modulator.

14. The apparatus of claim 1, wherein the scanning system is such that the plurality of possible locations in the first imaging plane at which the scanning system can form the image of the pattern are a plurality of locations which are different with respect to each other in the reference frame of the programmable spatial light modulator.

15. The apparatus of claim 1, wherein the scanning system comprises a two-dimensional beam scanner.

16. The apparatus of claim 1, wherein the programmable spatial light modulator comprises a plurality of individually addressable elements.

17. The apparatus of claim 16, wherein the programmable spatial light modulator comprises a two dimensional array of individually addressable elements.

18. The apparatus of claim 1, wherein the programmable spatial light modulator is configured to remain stationary during the forming of the plurality of images of the pattern at different locations in the first imaging plane.

19. A method of performing laser ablation on a substrate, comprising:
using a solid state laser to provide a pulsed laser beam;
inputting a control signal to a programmable spatial light modulator to modulate the pulsed laser beam with a pattern; and
forming in sequence a plurality of images in a first imaging plane of patterns defined by the spatial light modulator, the plurality of images being formed at different locations in the first imaging plane.

20-25. (canceled)

26. The method of claim 19, wherein the images formed in the first imaging plane are tessellated relative to each other.

27-33. (canceled)
